(19) United States
(12) Patent Application Publication
(10) Pub. No.: US 2011/0210312 A1
(43) Pub. Date: Sep. 1, 2011

(54) III-NITRIDE SEMICONDUCTOR LIGHT-EMITTING DEVICE AND MANUFACTURING METHOD THEREOF

(75) Inventors: Po Min Tu, Chia Yi (TW); Shih Cheng Huang, Hsinchu (TW); Ying Chao Yeh, Taipei (TW); Wen Yu Lin, Taichung (TW); Peng Yi Wu, Taichung (TW); Chih Peng Hsu, Tainan (TW); Shih Hsiung Chan, Hsinchu (TW)

(73) Assignee: ADVANCED OPTOELECTRONIC TECHNOLOGY, INC., Hsinchu Hsien (TW)

(21) Appl. No.: 13/106,872

(22) Filed: May 13, 2011

Related U.S. Application Data
(62) Division of application No. 12/268,650, filed on Nov. 11, 2008.

(30) Foreign Application Priority Data
Nov. 14, 2007 (TW) 96142955

(51) Int. Cl. H01L 33/02

(52) U.S. Cl. 257/13; 257/103; 257/E33.007

(57) ABSTRACT

A semiconductor light-emitting device includes a substrate, a buffer layer, an n-type semiconductor layer, a conformational active layer and a p-type semiconductor layer. The n-type semiconductor layer includes a first surface and a second surface, and the first surface directly contacts the buffer layer. The second surface includes a plurality of recesses, and a conformational active layer formed on the second surface and within the plurality of recesses. Widths of upper portions of the recesses are larger than widths of lower portions of the recesses. Therefore, the stress between the n-type semiconductor layer and the conformational active layer can be released with the recesses.

### RELATED APPLICATIONS

This application is a divisional application of prior-filed U.S. patent application Ser. No. 12/268,650 field Nov. 11, 2008, which is based on and claims priority from R.O.C. Patent Application No. 096142955 filed Nov. 14, 2007.

### BACKGROUND

1. Technical Field

The present disclosure relates to a III-nitride semiconductor light-emitting device and the manufacturing method thereof, and more particularly to a III-nitride semiconductor light-emitting device for releasing the stress between an conformational active layer and an n-type semiconductor layer.

2. Description of Related Art

Light-emitting diodes (LED) have been widely used in various products and have recently become an important research topic in photo-electronic semiconductor materials for producing blue light LED. Materials currently used for blue light LED include ZnSe, SiC, and InGaN, which are semiconductor materials exhibiting band gap properties with the gap energy of approximately over 2.6 eV. As the GaN series of light-emitting materials exhibits direct gap properties, they are able to generate light with high luminance and have the advantage of longer lifetime compared to the other similar direct gap material, such as ZnSe.

Typically, the structure of a blue light LED includes active layers of an InGaN/GaN quantum well structure. The quantum well structure is formed between an n-type GaN layer and a p-type GaN layer. When InGaN is grown with a high Indium content on GaN, there occurs a lattice mismatch between the GaN and the InGaN layer, and thus physical stress is induced between each of the layers. Therefore, an electric potential is generated to form piezoelectricity in response to the stress, resulting in a degradation of emission efficiency of the active layer.

FIG. 1 is a cross-sectional diagram showing a light-emitting diode disclosed in U.S. Pat. No. 6,345,063. The light-emitting diode 10 includes a substrate 11, a buffer layer 12, a n-type InGaN layer 13, an active layer 14, a first p-type III-V nitride layer 15, a second p-type III-V nitride layer 16, a p-type electrode 17 and an n-type electrode 18. The lattice constant of the active layer 14 matches that of the n-type InGaN layer 13, and thus the stress between these two layers is released. However, the n-type InGaN layer 13 is typically formed at a low temperature, which affects the quality of the epitaxial layers compared to the prior art GaN layer.

FIG. 2 is a cross-sectional diagram showing a light-emitting diode disclosed in U.S. Pat. No. 6,861,270. The light-emitting diode 20 includes a substrate 21, an n-type AlGaN layer 22, an active layer 23, a p-type AlGaN layer 24 and Ga or Al droplets 25. Due to the droplets 25 formed on the n-type AlGaN layer 22, a spatial fluctuation is produced in the bandgap such that light emission is better at the locations where the band gap is narrow. As a result, the light emitting efficiency can be increased even when dislocations are present. This patent discloses that the spatial fluctuation is produced by the lattice mismatch, and therefore this method is irrelevant to the solution of the lattice mismatch.

FIG. 3 is a cross-sectional diagram showing a light-emitting diode disclosed in U.S. Pat. No. 7,190,001. The light-emitting diode 30 includes a sapphire substrate 31, an AlN buffer layer 32, an n-type cladding layer 33, an AlN uneven layer 34, an active layer 35, a p-type cladding layer 36, a contact layer 37, a transparent electrode 38, a p-type electrode 391 and an n-type electrode 392. On the AlN uneven layer 34, the active layer 35 is formed. Therefore, the formation requirements of the active layer 35 can be simplified. However, the AlN uneven layer 34 is formed on the n-type cladding layer 33 by specific thermal treatment, which affects the quality of the epitaxial layers formed on the substrate.

In summary, the current market needs a semiconductor light-emitting device that can ensure low cost, high emission efficiency, and ease of implementation to eliminate all the drawbacks of the prior art described above.

### BRIEF DESCRIPTION OF THE DRAWINGS

The objectives and advantages of the present disclosure will become apparent upon reading the following description and upon reference to the accompanying drawings in which:

FIG. 1 is a cross-sectional diagram showing a light-emitting diode disclosed in U.S. Pat. No. 6,345,063;

FIG. 2 is a cross-sectional diagram showing a light-emitting diode disclosed in U.S. Pat. No. 6,861,270;

FIG. 3 is a cross-sectional diagram showing a light-emitting diode disclosed in U.S. Pat. No. 7,190,001;

FIG. 4 is a cross-sectional diagram showing a light-emitting diode of the present disclosure;

FIG. 5A is a partial cross-sectional diagram showing a light-emitting diode of the present disclosure; and

FIG. 5B is a top view of the partial cross-sectional diagram of FIG. 5A.

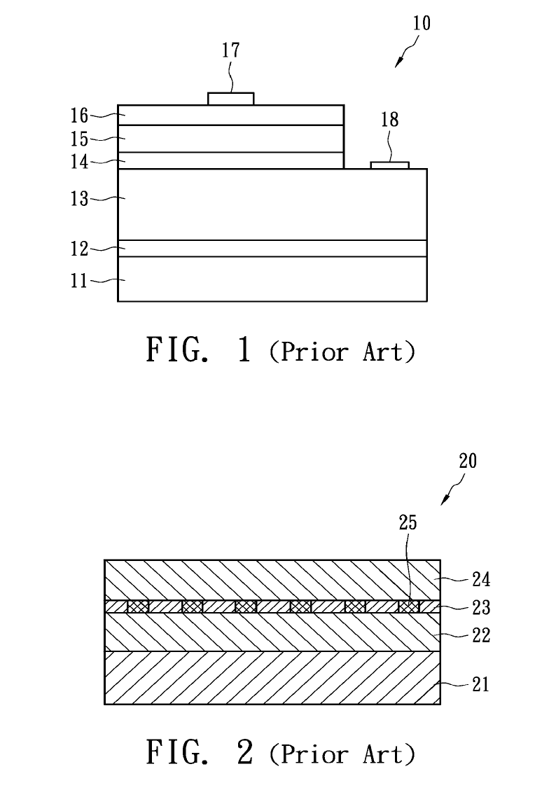

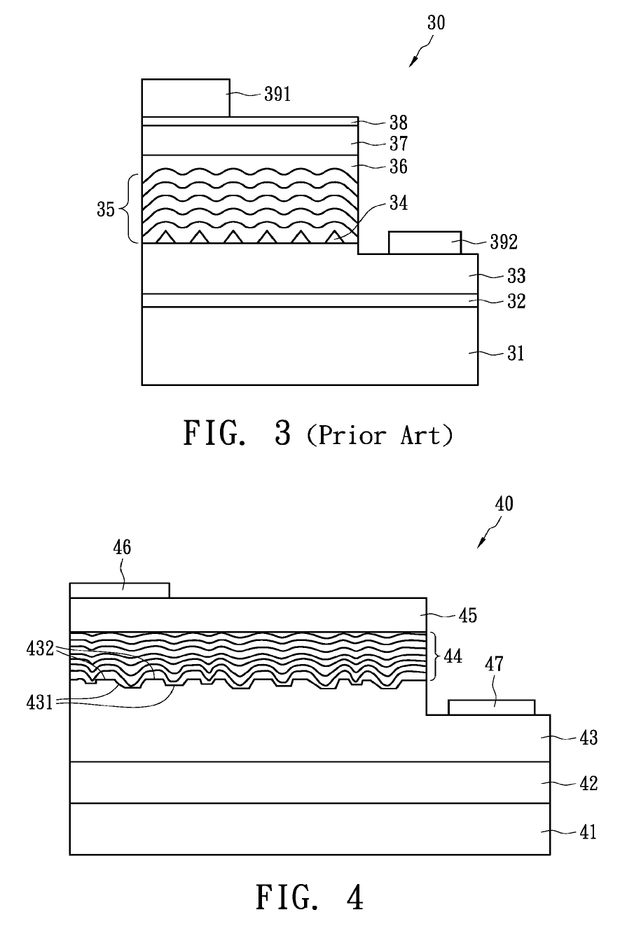

### DETAILED DESCRIPTION

Reference will now be made to the drawings to describe various inventive embodiments of the present disclosure in detail, wherein like numerals refer to like units throughout.

FIG. 4 is a cross-sectional diagram showing a light-emitting diode of the present disclosure. The light-emitting diode 40 includes a substrate 41, a buffer layer 42, an n-type (or first type) semiconductor layer 43, a conformational active layer 44 and a p-type (or second type) semiconductor layer 45. A p-type electrode 46 is formed on the p-type semiconductor layer 45 and an n-type electrode 47 is formed on the n-type semiconductor layer 43.

The substrate 41 can be formed by any known or later developed substrate materials, such as, for example, sapphire (i.e. Al.sub.2O.sub.3), silicon carbide (SiC), silicon, zinc oxide (ZnO), magnesium oxide (MgO) or gallium arsenide (GaAs). Subsequently, a semiconductor material is deposited over the substrate 41. Since the lattice mismatch occurs between the substrate 41 and the semiconductor material, at least one buffer layer 42 is required to form on the substrate 41. The buffer layer 42 is typically made of either GaN, InGaN, AlGaN or a superlattice structure whose hardness is lower than that of the traditional buffer layer with aluminum. The n-type semiconductor layer 43 is then formed on the buffer layer 42. The n-type semiconductor layer 43 may be formed as an n-type Si-doped GaN layer, epitaxially grown on the buffer layer 42. The top surface of the n-type semiconductor layer 43 is uneven and includes a plurality of recesses 431 and a flat area 432. Recesses 431 are grown in a MOCVD furnace. After the n-type semiconductor layer 43 with a thickness of 1 .mu.m to 5 .mu.m is formed, a flow rate of supply gases, such as nitrogen, ammonia, hydrogen, trimethylgallium (TMGa), triethylgallium (TEGa), trimethylindium (TMIn), triethylindium (TEIn) or organometallic compound, is stopped or reduced. Thus the top surface of the n-type semiconductor layer 43 is grown unevenly and the plurality of recesses 431 are formed. In addition, recesses 431 can be formed by etching the top surface of the n-type semiconductor layer 43.

Subsequently, the conformational active layer 44, in which holes and electrons are recombined to emit light, is formed on the n-type semiconductor layer 43. The conformational active layer 44 is a single quantum well (SQW) structure or a multiple quantum well (MQW) structure. The MQW structure is included of two to thirty light-emitting layers/barrier layers. In a preferred embodiment, the conformational active layer 44 is composed of six to eighteen layers. The light-emitting layers can be made of Al.sub.XIn.sub.YGa.sub.1-X-YN and the barrier layers can be made of Al.sub.IIn.sub.JGa.sub.1-I-JN, wherein 0.1toreq.X<1, 0.1toreq.Y<1, X+Y<1, 0.1toreq.I<1, 0.1toreq.J<1, I+J<1, and when X, Y, I, J>0, X.noteq.I and Y.noteq.J. Also, the light-emitting layers/barrier layers can be made of InGaN/GaN. In this structure, the stress between the n-type semiconductor layer 43 and the conformational active layer 44 can be released with recesses 431, and thus the emission efficiency can be increased. In addition, recesses 431 are formed without the deposition process on the epitaxial layer with different materials, or without the deposition of droplets. As a result, such method does not sacrifice the quality of the epitaxial layer and does not need an epitaxial layer as the n-type semiconductor layer 43, which sacrifices the epitaxial quality in order to match the lattice constant.

At least one p-type semiconductor layer 45 is then formed on the conformational active layer 44. The p-type semiconductor layers 45 may be formed as Mg-doped GaN and InGaN multi-layers, a superlattice structure of Mg-doped AlGaN/GaN and an Mg-doped GaN layer, or other forms. The p-side electrode 46 and the n-side electrode 47 then serve to allow the current to be applied to the p-type semiconductor layers 45 and the n-type semiconductor layer 43, respectively.

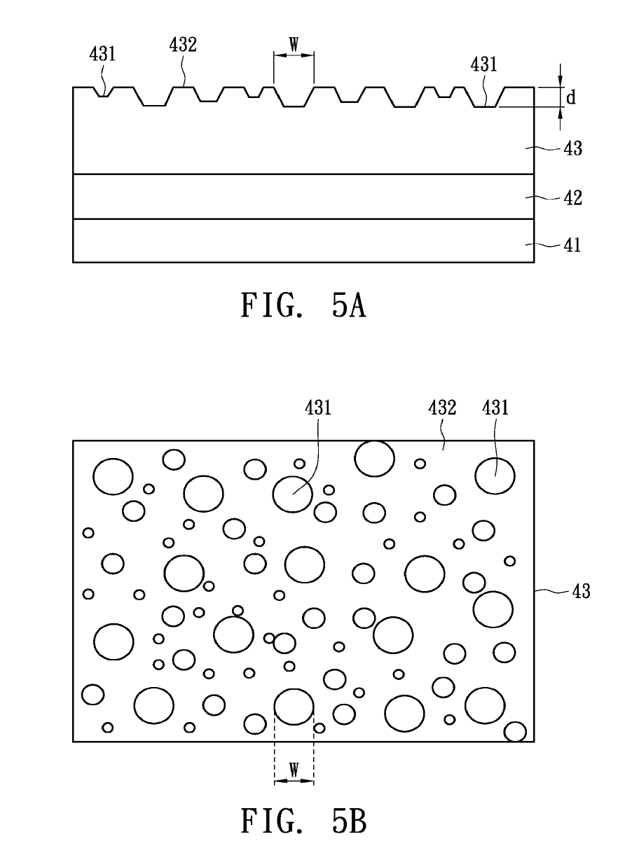

FIG. 5A is a partial cross-sectional diagram showing a light-emitting diode of the present disclosure. The buffer layer 42 and the n-type semiconductor layer 43 are grown in sequence on the substrate 41. Referring to FIG. 5A, the top surface of the n-type semiconductor layer 43 is uneven and includes the plurality of recesses 431 and the flat area 432. The depths of the accesses 431 may be larger than the depths of a single quantum well and smaller than the depth of the n-type semiconductor layer 43. In addition, a cross-sectional of the recesses 431 is substantially of an inverted trapezoid shape, and the widths W of the upper portions of the recesses range from 0.1 um to 10 um.

FIG. 5B is a top view of a partial cross-sectional diagram of FIG. 5A. Referring to FIG. 5B, the widths W or the diameters of the recesses 431 are not of uniform size and the distribution of recesses 431 is substantially uniform or non-uniform on the n-type semiconductor layer 43.

The above-described embodiments of the present disclosure are intended to be illustrative only. Those skilled in the art may devise numerous alternative embodiments without departing from the scope of the following claims.

It is to be understood, however, that even though numerous characteristics and advantages of certain inventive embodiments have been set out in the foregoing description, together with details of the structures and functions of the embodiments, the disclosure is illustrative only; and that changes may be made in detail, especially in matters of arrangement of parts within the principles of present disclosure to the full extent indicated by the broad general meaning of the terms in which the appended claims are expressed.

What is claimed is:

1. A III-nitride semiconductor light-emitting device, comprising:
a substrate;
a first type semiconductor layer comprising a first surface and a second surface wherein the first surface is disposed adjacent to the substrate and opposite to the second surface, and the second surface comprises a plurality of recesses;
a conformational active layer formed on the second surface and within the plurality of recesses; and
a second type semiconductor layer formed on the conformational active layer,
wherein widths of upper portions of the recesses are larger than widths of lower portions of the recesses.

2. The III-nitride semiconductor light-emitting device as claimed in claim 1, further comprising a buffer layer disposed between the substrate and the first type semiconductor layer.

3. The III-nitride semiconductor light-emitting device as claimed in claim 1, wherein the material of the substrate is sapphire, SiC, Si, ZnO, MgO or GaAs.

4. The III-nitride semiconductor light-emitting device as claimed in claim 1, wherein depths of the accesses are larger than a depth of a single quantum well in the active layer, and smaller than the depth of the first type semiconductor layer.

5. The III-nitride semiconductor light-emitting device as claimed in claim 1, wherein widths of upper portions of the recesses range from 0.1 um to 10 um.

6. The III-nitride semiconductor light-emitting device as claimed in claim 1, wherein the plurality of recesses have different sizes, and the distribution of the plurality of recesses is substantially uniform or non-uniform.

7. The III-nitride semiconductor light-emitting device as claimed in claim 1, wherein the conformational active layer is a single quantum well structure or a multiple quantum well structure.

8. The III-nitride semiconductor light-emitting device as claimed in claim 7, wherein the multiple quantum well structure includes two to thirty light-emitting layers and barrier layers, wherein the materials of the light-emitting layers and the barrier layers are InGaN and GaN.

9. The III-nitride semiconductor light-emitting device as claimed in claim 7, wherein the multiple quantum well structure includes two to thirty light-emitting layers and barrier layers, wherein the light-emitting layers are made of Al.sub.xIn.sub.YGa.sub.1-X-YN, and the barrier layers are made of Al.sub.IIn.sub.JGa.sub.1I-JN, wherein 0.1toreq.X<1, 0.1toreq.Y<1, X+Y<1, 0.1toreq.I<1, 0.1toreq.J<1, I+J<1, and when X, Y, I, J>0, X.noteq.I and Y.noteq.J.

10. The III-nitride semiconductor light-emitting device as claimed in claim 1, wherein the first type semiconductor layer is an n-type III-nitride semiconductor layer, and the second type semiconductor layer is a p-type semiconductor layer.

11. The III-nitride semiconductor light-emitting device as claimed in claim 1, wherein the first type semiconductor layer is an n-type Si-doped GaN layer, and the second type semiconductor layer is formed as Mg-doped GaN and InGaN multi-layers, or a superlattice structure of Mg-doped AlGaN/GaN and a Mg-doped GaN layer.

12. The III-nitride semiconductor light-emitting device as claimed in claim 1, further comprising a first type electrode and a second type electrode, wherein the first type electrode is disposed on the first type semiconductor layer, and the second type electrode is disposed on the second type semiconductor layer.
